(19) United States
(12) Patent Application Publication
(10) Pub. No.: US 2023/0087294 A1
(43) Pub. Date: Mar. 23, 2023

(54) ASSEMBLED BATTERY TESTING METHOD

(71) Applicant: Prime Planet Energy & Solutions, Inc., Tokyo (JP)

(72) Inventor: Reizo MAEDA, Himeji-shi (JP)

(21) Appl. No.: 17/932,291

(22) Filed: Sep. 15, 2022

(30) Foreign Application Priority Data
Sep. 17, 2021 (JP) 2021-152471

(51) Int. Cl. G01R 31/392; G01R 31/396

(52) U.S. Cl. CPC G01R 31/392; G01R 31/396

(57) ABSTRACT

The testing method disclosed herein tests the thermal propagation occurred in the assembled battery. The testing method includes: calculating a reference voltage value V_{S} based on the voltages of the single batteries; testing thermal propagation based on the reference voltage value V_{S} and the voltages of the single batteries. In the testing, if a first voltage difference (V_{S}−V₁) between a voltage V₁ of a predetermined first single battery and the reference voltage value V_{S} is a first threshold value V_{T1} or more, and a second voltage difference (V_{S}−V₂) between a voltage V₂ of a second single battery adjacent to the first single battery and the reference voltage value V_{S} is a second threshold value V_{T2} or more, it is determined that the thermal propagation is occurring. According to such a testing method, the thermal propagation occurred can be detected accurately in an early stage.

### CROSS REFERENCE TO RELATED APPLICATIONS

The present application is based upon and claims the benefit of priority from Japanese patent application No. 2021-152471 filed on Sep. 17, 2021, and the entire disclosure of which is incorporated herein in its entirety by reference.

### BACKGROUND

### 1. Technical Field

The present disclosure relates to an assembled battery testing method. Specifically, the present disclosure relates to a method of testing thermal propagation in an assembled battery including multiple single batteries.

### 2. Description of the Related Art

Secondary batteries such as lithium-ion secondary batteries and nickel hydride batteries are widely used in various fields. In fields where high-output power source such as a power source for vehicles are required, an assembled battery including multiple secondary batteries is used. In the assembled battery, multiple secondary batteries (hereinafter, also referred to as “single batteries”) are arranged adjacent to each other generally. The single batteries aligned are electrically connected to each other via connection members.

Secondary batteries (single batteries) may generate heat due to damage to constituent members (especially separators) of the electrode body and excessive charging/discharging. When one single battery in the assembled battery with this configuration generates heat, the adjacent single batteries are heated, thereby accelerating the heat generation of the adjacent single batteries. If this accelerated heat generation due to heat transfer between the single batteries occurs in a chain reaction, the entire assembled battery may become very hot. In order to prevent the increase in temperature of the entire assembled battery due to the progression of such thermal propagation, a technique of detecting the thermal propagation in an early stage has been proposed. For example, JP 2021-12793 proposes a technique of detecting thermal propagation based on changes of voltages of the single batteries. In this technology described in JP 2021-12793, it is determined that the thermal propagation is occurring when, after detection of steep voltage drop in one battery cell (single battery), a steep voltage drop is detected in at least one of the other battery cells within the first time. Here, the “steep voltage drop” in the technology described in JP2021-12793 means that the voltage of the battery cell drops to around 0 V in a relatively short time.

### SUMMARY

The increasing demand for safety in recent years has led to a need for a technology that can more accurately detect thermal propagation in an earlier stage than the technology described in JP 2021-12793. Specifically, as mentioned above, in this technology described in JP 2021-12793, it is determined that the thermal propagation is occurring when a steep voltage drop (a voltage drop to around 0 V) occurs in a specific single battery, and then a steep voltage drop (a voltage drop to around 0 V) occurs in another single battery before a first time elapses. However, the heating itself of the single battery occurs before the voltage drops to around 0 V. This may progress the thermal propagation before measurement of the first time. In addition, with the technology described in JP 2021-12793, the thermal propagation is not detected until voltages of the other single batteries drop to around 0 V. Therefore, by the time point when thermal propagation occurring is detected, the thermal propagation may have progressed to the level that is difficult to deal with.

As a means of detecting thermal propagation in an earlier stage, it is considered to set the voltage value (hereinafter, referred to as a “reference voltage value”) to be a determination criteria for determining whether or not a single battery is generating heat to be a value higher than around 0 V. However, when the reference voltage value is set to be a high value, changes in voltage during normal charging/discharging reaction may cause a single battery with a voltage lower than the reference voltage value, resulting in an erroneous detection.

The present disclosure was made to solve the problems, and is intended to provide an assembled battery testing method which can more accurately detect thermal propagation occurring in an assembled battery in an earlier stage than traditional methods.

In order to achieve the objective, an assembled battery testing method disclosed herein is provided.

The assembled battery testing method disclosed herein (hereinafter, also referred to as the “testing method”) is to test thermal propagation occurring in an assembled battery including multiple single batteries arranged adjacent to each other along a predetermined alignment direction. The testing method includes: measuring voltages of the single batteries; calculating a reference voltage value V_{S} based on the voltages of the single batteries; and testing the thermal propagation based on the reference voltage value V_{S} and the voltages of the single batteries. In the testing of the testing method disclosed herein, if a first voltage difference (V_{S}−V₁) between a voltage V₁ of a predetermined first single battery and the reference voltage value V_{S} is a first threshold value V_{T1} or more, and a second voltage difference (V_{S}−V₂) between a voltage V₂ of a second single battery adjacent to the first single battery and the reference voltage value V_{S} is a second threshold value V_{T2} or more, it is determined that the thermal propagation is occurring in the single batteries.

In the testing method disclosed herein, the reference voltage value V_{S} is a value calculated based on the voltages of the single batteries. In the testing method disclosed herein, absolute evaluation of comparing with a reference voltage value fixed to a predetermined value (e.g., around 0 V) is not performed. That is, in the testing method disclosed herein, relative evaluation of comparing between the reference voltage value V_{S} calculated based on current voltages of the single batteries and the voltages of the single batteries is performed. The testing method allows detection of a single battery having an abnormal voltage drop compared with other single batteries, and detection of whether or not thermal propagation is occurring around the single battery. Therefore, unlike traditional technology that fixes the reference voltage value to around 0 V, thermal propagation occurring can be detected before a voltage of a specific single battery drops to around 0 V. Furthermore, the reference voltage value V_{S} in the technology disclosed herein is calculated based on the voltages of the single batteries which vary with the charging/discharging reaction. This also allows a reduction in erroneous detection caused by the changes in voltage with a charging/discharging reaction.

In a preferred aspect of the testing method disclosed herein, the reference voltage value V_{S} is an average voltage Vₐᵥₑ of the single batteries. This allows more accurate detection of thermal propagation occurring.

In a preferred aspect of the testing method disclosed herein, the reference voltage value V_{S} is an average voltage Vₐᵥₑ₍ₙ₋₂₎ of the other single batteries excluding the first single battery and the second single battery from the single batteries. This allows more accurate detection of occurrence of the thermal propagation occurring.

In a preferred aspect of the testing method disclosed herein, the reference voltage value V_{S} is a maximum voltage Vₘₐₓ of the single batteries. This allows detection of thermal propagation in an earlier stage.

In a preferred aspect of the testing method disclosed herein, in the testing, if the first voltage difference (V_{S}−V₁) is the first threshold value V_{T1} or more, whether or not the second voltage difference (V_{S}−V₂) is the second threshold value V_{T2} or more is continuously determined during a testing time set in advance. This allows more accurate detection of occurrence of the thermal propagation occurring. The testing time is, for example, set preferably in a range of 15 seconds to 450 seconds.

In a preferred aspect of the testing method disclosed herein, in the testing, if the voltage V₁ of the first single battery and the voltage V₂ of the second single battery are a predetermined second reference voltage value V_{S2} or less, it is determined that the thermal propagation is occurring in the single batteries. In this aspect, the testing method further includes testing of thermal propagation based on absolute evaluation using the second reference voltage value V_{S2} which is a fixed value set in advance. This allows more reliable detection of thermal propagation. In this case, the second reference voltage value V_{S2} is set to preferably 1 V or less.

### BRIEF DESCRIPTION OF THE DRAWINGS

FIG. 1 is a perspective view schematically illustrating an example of a structure of an assembled battery.

FIG. 2 is a perspective view schematically illustrating a single battery in FIG. 1.

FIG. 3 is a flowchart illustrating a testing method according to an embodiment.

FIG. 4 is a schematic view illustrating calculation of a reference voltage value V_{S} in the embodiment.

FIG. 5 is a schematic view illustrating calculation of a reference voltage value V_{S} in another embodiment.

FIG. 6 is a schematic view illustrating calculation of a reference voltage value V_{S} in another embodiment.

### DETAILED DESCRIPTION

The following describes embodiments of the technology disclosed herein. The matters necessary for executing the technology disclosed herein, except for matters specifically herein referred to (e.g., the detailed structure and manufacturing processes of the assembled battery) can be grasped as design matters of those skilled in the art based on the related art in the preset field. The technology disclosed herein can be executed based on the contents disclosed herein and the technical knowledge in the present field. The expression “A to B” indicating herein a range means A or more to B or less, and also encompasses the meaning of “preferably more than A” and “preferably less than B.”

The “secondary battery” herein generally refers to an electricity storage device which causes a charging/discharging reaction by movement of charge carriers between a pair or electrodes (a positive electrode and a negative electrode) via an electrolyte. The “secondary battery” herein encompasses so-called secondary batteries such as a lithium-ion secondary battery, a nickel hydride battery and a nickel cadmium battery, and capacitors such as an electric double-layer capacitor.

An embodiment of the testing method disclosed herein will be described below. The testing method is a method of testing thermal propagation occurring in an assembled battery. The following describes an example of the structure of the assembled battery which is a testing target, and then describes specific testing procedures.

### 1. Structure of Assembled Battery

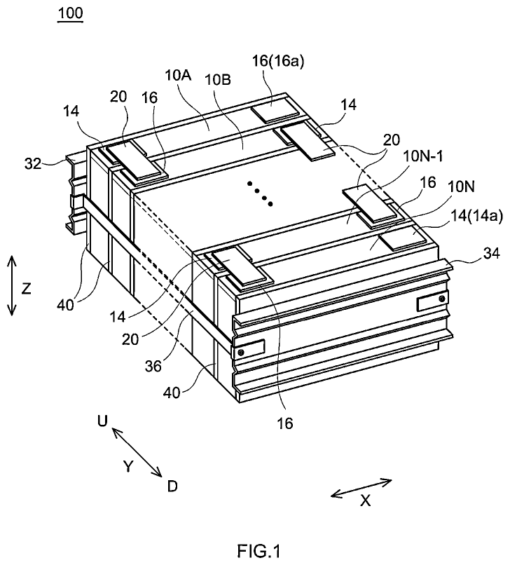

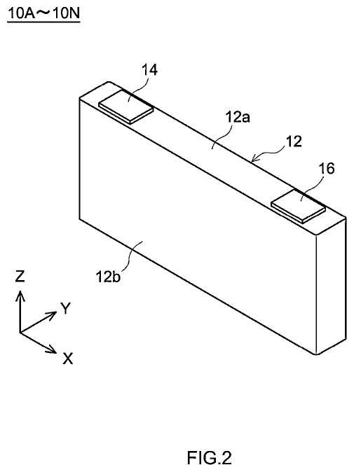

FIG. 1 is a perspective view schematically illustrating an example of a structure of an assembled battery. FIG. 2 is a perspective view schematically illustrating a single battery in FIG. 1. In FIGS. 1 and 2, the reference sign X indicates “the width direction (of a single battery),” the reference sign Y indicates “the alignment direction (of a single battery),” and the reference sign Z indicates “the height direction (of a single battery).” In the alignment direction Y, U indicates an “upstream side,” and D indicates a “downstream side.” These directions are defined for convenience of explanation and are not intended to limit the technology disclosed herein.

An assembled battery 100 shown in FIG. 1 includes a plurality of (N) single batteries 10A to 10N. As shown in FIG. 2, each of the single batteries 10A to 10N includes a battery case 12 which is a flat square container. The battery case 12 is made of a metal material having predetermined rigidity such as aluminum. Although not shown in the drawings, the battery case 12 contains an electrode body where charging/discharging reaction occurs and an electrolyte therein. A positive electrode terminal 14 and a negative electrode terminal 16 are attached to the upper surface 12a of the battery case 12. Although not shown in the drawings, the positive electrode terminal 14 is electrically connected to a positive electrode of the electrode body inside the battery case 12. The negative electrode terminal 16 is electrically connected to a negative electrode of the electrode body inside the battery case 12.

As shown in FIG. 1, in the assembled battery 100, multiple single batteries 10A to 10N are arranged adjacent to each other along the predetermined alignment direction Y. The single batteries 10A to 10N aligned are electrically connected to each other via connection members 20. Specifically, the single batteries 10A to 10N are arranged so that their long side surfaces 12b (see FIG. 2) of the respective battery cases 12 face each other. At this time, the single batteries 10A to 10N are arranged such that the positive electrode terminal 14 of one of the adjacent single batteries comes close to the negative electrode terminal 16 of the other single battery. The positive electrode terminal 14 of one single battery is electrically connected to the negative electrode terminal 16 of the other single battery via a connection member 20. The negative electrode terminal 16 of the single battery 10A arranged at the upstream U end in the alignment direction Y is not connected to the adjacent single battery 10B. The negative electrode terminal 16 of the single battery 10A is a negative electrode output terminal 16a, which is connected to an external device (e.g., vehicle motor). Similarly, the positive electrode terminal 14 of the single battery 10N arranged at the downstream D end in the alignment direction Y is not connected to the adjacent single battery 10N-1. The positive electrode terminal 14 of this single battery 10N is a positive electrode output terminal 14a, which is connected to an external device.

In the assembled battery 100, multiple single batteries 10A to 10N are bonded along the alignment direction Y. Specifically, a pair of binding plates 32 and 34 are arranged on both outer sides of the assembled battery 100 in the alignment direction X. With the single batteries 10A to 10N sandwiched between the binding plates 32 and 34 in pair, the binding plates 32 and 34 are crosslinked with a crosslinking member 36. This binds the single batteries 10A to 10N along the alignment direction Y. In the assembled battery 100 shown in FIG. 1, a rectangular buffer plate 40 is arranged between adjacent single batteries. This allows uniform binding pressure to be applied to the long side surfaces 12b (see FIG. 2) of the battery cases 12.

### 2. Assembled Battery Testing Method

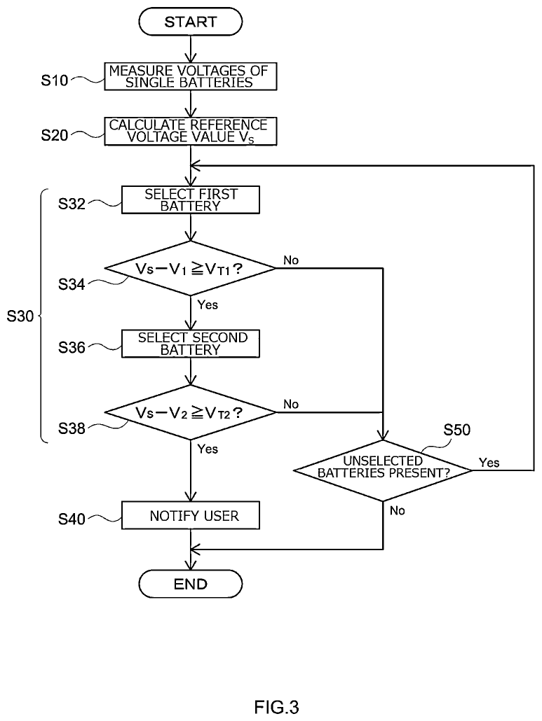

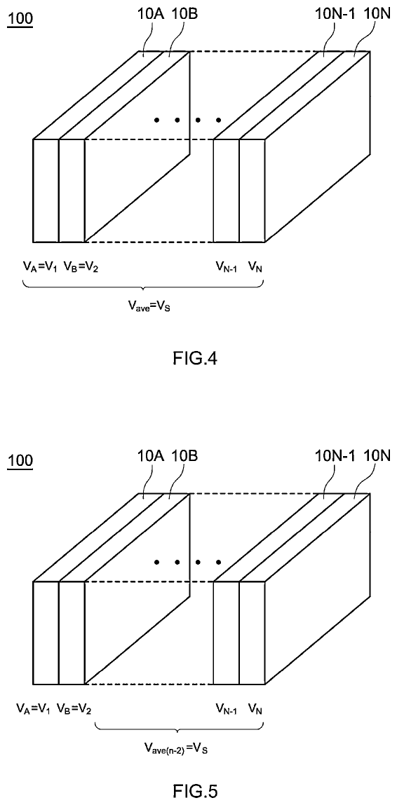

Next, the assembled battery testing method according to the present embodiment, targeted for the assembled battery 100 with the configuration described above will be described. FIG. 3 is a flowchart illustrating a testing method according to the present embodiment. FIG. 4 is a schematic view illustrating calculation of a reference voltage value V_{S} in the present embodiment.

The testing method according to the present embodiment includes voltage measurement, reference voltage calculation, and testing. Each process will be described below.

### (1) Voltage Measurement

In step S10 of FIG. 3, voltage measurement of measuring voltages V_{A} to V_{N} of multiple single batteries 10A to 10N is performed. A means for measuring the voltages V_{A} to V_{N} of the single batteries 10A to 10N is not particularly limited, and known means can be employed without particular limitations.

### (2) Reference Voltage Calculation

In step S20, reference voltage calculation of calculating a reference voltage value V_{S} is performed. As mentioned above, the “reference voltage value” herein means a voltage value to be a determination criteria for determining whether or not the single battery is generating heat. In the testing method according to the present embodiment, a value calculated based on the voltages V_{A} to V_{N} of the single batteries 10_{A} to 10_{N} constituting the assembled battery 100 is employed as the reference voltage value V_{S}, instead of a constant value set in advance. As described in detail below, the use of the reference voltage value V_{S} based on the voltages of the single batteries allows detection of a single battery which has an abnormal voltage drop in an early stage compared with the other single batteries. As shown in FIG. 4, in the testing method according to the present embodiment, an average voltage Vₐᵥₑ of the single batteries 10A to 10N constituting the assembled battery 100 is employed as the reference voltage value V_{S}. A single battery with a large voltage difference from the average voltage Vₐᵥₑ can be regarded as having an abnormal voltage drop. A single battery rapidly generating heat due to internal short-circuit or the like usually causes steep voltage drop. In other words, a single battery with a large voltage difference from the reference voltage value V_{S} (average voltage Vₐᵥₑ) can be regarded as rapid generation of heat.

### (3) Testing

Next, in step S30, testing of thermal propagation is performed based on the reference voltage value V_{S} and the voltages V_{A} to V_{N} of the single batteries 10A to 10N. As shown in FIG. 3, the testing (step S30) in the present embodiment includes the following steps S32 to S38. The following describes the steps.

In the testing of the present embodiment, step S32 of selecting a first single battery to be a testing target among the single batteries 10A to 10N is performed. The first single battery to be a testing target can be arbitrarily selected without particular limitations. The following describes a case where a single battery 10A (see FIG. 1) arranged at an upstream U end in the alignment direction Y is selected as the first single battery as an example.

Then, in step S34, a first voltage difference (V_{S}−V₁) between the voltage V₁ of the first single battery (the voltage V_{A} of the single battery 10A) and the reference voltage value V_{S} (average voltage Vₐᵥₑ) is calculated. In step S34, whether or not the first voltage difference is a first threshold value V_{T1} or more (V_{S}−V₁≥V_{T1}?) is further determined. The first threshold value V_{T1} set in step S34 is a value set in consideration of the amount of voltage drop in the secondary battery which has rapidly generated heat. The first threshold value V_{T1} is set, as appropriate, in consideration of the results of preliminary tests and the like. The first threshold value V_{T1} may be set in a range of 50 mV to 150 mV (e.g., 100 mV) although it does not limit the technology disclosed herein. In step S34, if the first voltage difference (V_{S}−V₁) is the first threshold value V_{T1} or more (YES), it is determined that rapid heat generation is occurring in the first single battery (single battery 10A). In this case, the process proceeds to step S36. On the other hand, in step S34, if the first voltage difference (V_{S}−V₁) is less than the first threshold value V_{T1} (NO), it is determined that rapid head generation is not occurring in the first single battery (single battery 10A). In this case, the process proceeds to step S50. The step S50 will be described in detail later.

Then, in step S36, a single battery adjacent to the first single battery is selected as a second single battery. In the present embodiment, a single battery adjacent to the first single battery on the downstream side D in the alignment direction X is selected as the second single battery, although it does not limit the technology disclosed herein. For example, when the single battery 10A in FIG. 1 is the first single battery, the single battery 10B adjacent to the downstream side D of the single battery 10A is selected as the second single battery.

Then, in step S38, a second voltage difference (V_{S}−V₂) between the voltage V₂ of the second single battery (the voltage V_{B} of the single battery 10B) and the reference voltage value V_{S} (average voltage Vₐᵥₑ) is calculated. In step S38, whether or not the second voltage difference is a second threshold value V_{T2} or more (V_{S}−V₂≥V_{T2}?) is further determined. Similarly to the first threshold value VT1, the second threshold value V_{T2} is a value set in consideration of the amount of voltage drop in the secondary battery which has rapidly generated heat. In other words, the second threshold value V_{T2} is set, as appropriate, in consideration of the results of preliminary tests and the like. The second threshold value V_{T2} may be set to a value which is the same as or difference from the first threshold value VT₁. The second threshold value V_{T2} may also be set in a range of 50 mV to 150 mV (e.g., 100 mV) although it does not limit the technology disclosed herein.

In step S38, it is preferable that the determination of whether or not the second voltage difference (V_{S}−V₂) is the second threshold value V_{T2} or more is continuously performed during the testing time set in advance. This allows the time lag between heat generation occurred in the first single battery and the propagation of the heat to the second single battery to be taken into account. As a result, the thermal propagation can be detected more accurately. The testing time set in step S34 is not particularly limited, and can be set, as appropriate, considering the results of the preliminary tests measuring thermal transfer rate between single batteries. As an example, the testing time is set preferably in a range of 15 seconds to 450 seconds (e.g., 300 seconds).

In step S38, if the second voltage difference (V_{S}−V₂) is the second threshold value V_{T2} or more (YES), it is determined that rapid heat generation is occurring in both of the first single battery (the single battery 10A) and the second single battery (the single battery 10B). In other words, if YES in step S38, it is determined that the thermal propagation is occurring between the single batteries 10A and 10B. In this case, the process proceeds to step S40, a user is notified of the occurrence of the thermal propagation, and the testing for the thermal propagation is ended. A means for notifying the user of the occurrence of the thermal propagation is not particularly limited, and for example, visual indication (indication on a display), notification by voice and the like (notification by alarm), and the like can be employed without particular limitations.

On the other hand, if it is determined that rapid heat generation is not generated in the first single battery (step S34: NO), or it is determined that thermal propagation is not occurring between the first single battery and the second single battery (step S38: NO), the process proceeds to step S50 to check the presence of unselected batteries. Specifically, in step S50, whether or not a single battery (an unselected battery) which has not been selected as the testing target (first single battery) is present among the single batteries 10A to 10N constituting the assembled battery 100 is checked. If unselected batteries are present (YES), the testing process returns to step S32, and a first single battery is selected among the unselected batteries to test again. On the other hand, when no unselected battery is present (NO), it is determined that thermal propagation is not occurring in all the single batteries 10A to 10N constituting the assembled battery 100, and the testing process is ended.

As described above, in the testing method according to the present embodiment, when the first voltage difference (V_{S}−V₁) between the voltage V₁ of the first threshold value V_{T1} and the reference voltage value V_{S} is the first threshold value V_{T1} or more, and the second voltage difference (V_{S}−V₂) between the voltage V₂ of the second single battery adjacent to the first single battery and the reference voltage value V_{S} is the second threshold value V_{T2} or more, it is determined that the thermal propagation between the first single battery and the second single battery is occurring. In the testing method with such a configuration, relative evaluation of comparing the reference voltage value V_{S} based on the current voltages V_{A} to V_{N} of the single batteries 10A to 10N and the voltages V_{A} to V_{N} of the single batteries 10A to 10N is performed. This allows detection of a single battery having an abnormal voltage drop compared with other single batteries, and detection of whether or not thermal propagation is occurring around the single battery. In the testing method according to the present embodiment, thermal propagation occurring is detected at the time when abnormal voltage drop is confirmed. Therefore, the thermal propagation can be detected earlier than the case where the thermal propagation cannot be detected until the voltage drops to around 0 V. The reference voltage value V_{S} (the average voltage Vₐᵥₑ) in the present embodiment reflects changes in voltage of each single battery with charging/discharging. This also allows a reduction in erroneous detection caused by changes in voltage with a charging/discharging reaction.

### 3. Other Embodiments

An embodiment of the testing method disclosed herein was described above. The embodiment is not intended to limit the testing method disclosed herein, and various changes can be made.

### (1) Calculation of Reference Voltage Value V_{S}

In the embodiment, an average voltage Vₐᵥₑ is employed as the reference voltage value V_{S}. However, the reference voltage value V_{S} is not particularly limited as long as it does not impair effects of the technology disclosed herein, and a voltage value other than the average voltage Vₐᵥₑ can also be employed.

For example, as shown in FIG. 4, the average voltage Vₐᵥₑ employed in the embodiment includes voltages of single batteries to be testing targets (the voltage V₁ of the first single battery and the voltage V₂ of the second single battery). Thus, when the voltage V₁ of the first single battery and the voltage V₂ of the second single battery are significantly reduced, the reference voltage value V_{S} (the average voltage Vₐᵥₑ) may be a value lower than the normal voltage value. Accordingly, when an average voltage is employed as the reference voltage value V_{S}, it is suitable to calculate the average voltage Vₐᵥₑ₍ₙ₋₂₎ of the other single batteries excluding the first single battery and the second single battery from the multiple single batteries 10A to 10N constituting the assembled battery 100, as shown in FIG. 5. This allows more accurate detection of thermal propagation.

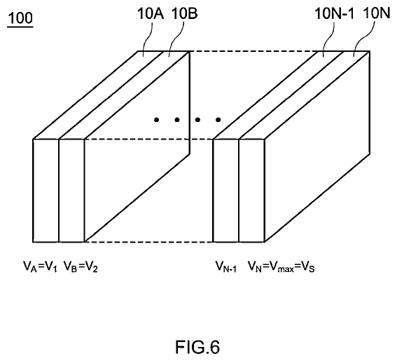

As the reference voltage value V_{S}, a voltage value other than the average voltage can also be employed. Another example of the reference voltage value V_{S} can be the maximum voltage Vₘₐₓ in the single batteries 10A to 10N constituting the assembled battery 100 (see FIG. 6). When the maximum voltage Vₘₐₓ is employed as the reference voltage value V_{S}, the voltage differences (V_{S}−V₁ and V_{S}−V₂) from the reference voltage value V_{S} become large. This makes it easier to detect a single battery with slightly reduced voltage in an early stage of heat generation. Although detailed description is omitted, the reference voltage value V_{S} may be the median value or mode value of the voltages V_{A} to V_{N} of the single batteries 10A to 10N, in addition to the average value and the maximum value mentioned above.

### (2) Selection of First Single Battery

In the testing method according to the embodiment, as shown in step S32 in FIG. 3, one single battery is selected as the first battery (testing target) from among multiple single batteries 10A to 10N, and whether or not thermal propagation is occurring around the first battery is tested. Then, if the thermal propagation is not occurring around the first battery, the testing process returns to step S32 through step S50, and a first single battery is again selected from among unselected batteries, and subjected to testing. However, the process of selecting the first single battery to be a testing target is not limited to the embodiment. For example, the reference voltage value V_{S} and the voltage differences (V_{S}−V_{A} to V_{S}−V_{N}) may be calculated for all voltages V_{A} to V_{N} of the single batteries 10A to 10N. Then, a process of regarding a single battery where the calculated voltage difference (V_{S}−V_{A} to V_{S}−V_{N}) is a first threshold value V_{T1} or more as the “first single battery” and testing whether or not the thermal propagation is occurring around the first single battery may also be employed.

### (3) Selection of Second Single Battery

In the testing method according to the embodiment, a single battery adjacent to the downstream side of the first single battery is regarded as a second single battery, and whether or not an abnormal voltage drop is occurring in the second single battery is determined to test the occurrence of the thermal propagation (see steps S36 and S38 in FIG. 3). However, the process of selecting the second single battery is not limited to the embodiment. For example, a pair of single batteries arranged on both sides of the first single battery may be both regarded as second single batteries. In this case, if at least one of the second single batteries in pair has an abnormal voltage drop, it can be determined that thermal propagation is occurring.

### (4) Setting of Second Reference Voltage Value V_{S2}

As mentioned above, the testing method disclosed herein is characterized in that relative evaluation of comparing the reference voltage value V_{S} calculated based on the voltages of the single batteries and the voltages of the single batteries is performed, and a single battery having an abnormal voltage drop is detected. However, such a characteristic does not negate the combination with absolute evaluation, which involves comparing with a reference voltage value fixed to a predetermined value. In the testing method disclosed herein, absolute evaluation where it is determined that thermal propagation is occurring when the voltage V₁ of the first single battery and the voltage V₂ of the second single battery are the predetermined second reference voltage value V_{S2} or less may be performed in addition to the relative evaluation of comparing with the first reference voltage value V_{S1} calculated based on the voltages of the single batteries. This allows more reliable detection of the occurrence of the thermal propagation even if all of the single batteries constituting the assembled battery have steep voltage drops, and the first reference voltage value V_{S1} largely decreases. The second reference voltage value V_{S2} may be a value set in consideration of the voltage value of the secondary battery which is rapidly generating heat. For example, the second reference voltage value V_{S2} can be set, as appropriate, in consideration of the results of the preliminary tests. The second reference voltage value V_{S2} is preferably 1 V or less, more preferably 0.5 V or less, particularly preferably 0.1 V or less (e.g., around 0 V), although it does not limit the technology disclosed herein.

Although the technology disclosed herein has been described in detail above with specific embodiments, it is a mere example and does not limit the appended claims. The technology described is the appended claims include various modifications and changes of the foregoing embodiments.

What is claim is:

1. An assembled battery testing method of testing thermal propagation occurring in an assembled battery including multiple single batteries arranged adjacent to each other along a predetermined alignment direction,
the method comprising:
measuring voltages of the single batteries;
calculating a reference voltage value V_{S} based on the voltages of the single batteries; and
testing the thermal propagation based on the reference voltage value V_{S} and the voltages of the single batteries, wherein
in the testing, if a first voltage difference (V_{S}−V₁) between a voltage V1 of a predetermined first single battery and the reference voltage value V_{S} is a first threshold value V_{T1} or more, and a second voltage difference (V_{S}−V₂) between a voltage V₂ of a second single battery adjacent to the first single battery and the reference voltage value V_{S} is a second threshold value V_{T2} or more, it is determined that the thermal propagation is occurring in the single batteries.

2. The assembled battery testing method according to claim 1, wherein the reference voltage value V_{S} is an average voltage Vₐᵥₑ of the single batteries.

3. The assembled battery testing method according to claim 1, wherein the reference voltage value V_{S} is an average voltage Vₐᵥₑ₍ₙ₋₂₎ of the other single batteries excluding the first single battery and the second single battery from the single batteries.

4. The assembled battery testing method according to claim 1, wherein the reference voltage value V_{S} is a maximum voltage Vₘₐₓ of the single batteries.

5. The assembled battery testing method according to claim 1, wherein in the testing, if the first voltage difference (V_{S}−V₁) is the first threshold value V_{T1} or more, whether or not the second voltage difference (V_{S}−V₂) is a second threshold value V_{T2} or more is continuously determined during a testing time set in advance.

6. The assembled battery testing method according to claim 5, wherein the testing time is set in a range of 15 seconds to 450 seconds.

7. The assembled battery testing method according to claim 1, wherein in the testing, if the voltage V₁ of the first single battery and the voltage V₂ of the second single battery are a predetermined second reference voltage value V_{S2} or less, it is determined that the thermal propagation is occurring in the single batteries.

8. The assembled battery testing method according to claim 7, wherein the second reference voltage value V_{S2} is 1 V or less.
